(19) United States
(12) Patent Application Publication
(10) Pub. No.: US 2016/0344920 A1
(43) Pub. Date: Nov. 24, 2016

(54) IMAGE CAPTURING APPARATUS AND METHOD OF CONTROLLING THE SAME

(71) Applicant: CANON KABUSHIKI KAISHA, Tokyo (JP)

(72) Inventor: Tomonaga Iwahara, Atsugi-shi (JP)

(21) Appl. No.: 15/110,865

(22) PCT Filed: Jan. 20, 2015
(86) PCT No.: PCT/JP2015/051949

§ 371 Date: Jul. 11, 2016

(30) Foreign Application Priority Data
Feb. 6, 2014 (JP) 2014-021703
Nov. 14, 2014 (JP) 2014-231974

(51) Int. Cl. H04N 5/232; H04N 5/369; H04N 5/347; H04N 5/378; H04N 5/343

(52) U.S. Cl. CPC H04N 5/23212; H04N 5/378; H04N 5/343; H04N 5/347; H04N 5/3696

(57) ABSTRACT

An image capturing apparatus includes a plurality of unit pixels arranged in matrix and each including a plurality of photoelectric conversion portions, and an AD converter configured to receive a signal from each unit pixel via a vertical signal line and operate in the first AD conversion mode when being set in the first readout mode, and operates in the second AD conversion mode different from the first AD conversion mode when being set in the second readout mode. The first readout mode is a mode of independently outputting signals from a plurality of photoelectric conversion portions to a corresponding vertical signal line. The second readout mode is a mode of composing and outputting signals from a plurality of photoelectric conversion portions to a corresponding vertical signal line.

### TECHNICAL FIELD

The present invention relates to an image capturing apparatus and a method of controlling the same.

### BACKGROUND ART

Recently, there has been proposed an image capturing apparatus which can perform not only image capture but also distance measurement by outputting a plurality of signals from a unit pixel.

For example, Japanese Patent Laid-Open No. 2001-124984 discloses a technique capable of performing focus detection by a pupil division method. According to Japanese Patent Laid-Open No. 2001-124984, an image sensor includes a multi-pixel structure in which two photodiodes (to be referred to as PDs hereinafter) are formed per microlens. Each PD is configured to receive light passing through different pupils of an imaging lens. It is therefore possible to perform imaging plane AF and acquire a distance image by comparing output signal waveforms from two PDs. In addition, it is possible to obtain a normal shot image by adding output signals from two PDs.

On the other hand, Japanese Patent No. 5110519 discloses a technique capable of performing distance measurement by a so-called light travel time method or TOF (time of Flight) method. According to Japanese Patent No. 5110519, one pixel of an image sensor includes two floating diffusions (to be referred to as FDs hereinafter) and two transfer switches per PD. The charges generated by reflected light are distributed from one PD to two FDs by alternately opening and closing two transfer switches in synchronism with the pulse timing of projection light. The distance to the object can be estimated from the distribution ratio of charges.

Recently, as a method of AD-converting analog signals read out from pixels of an image sensor, the mainstream is a column AD conversion method of concurrently performing AD conversion for each column. This column AD conversion method is advantageous in easily increasing the readout speed of an image sensor as well as being able to increase the time scale of AD conversion from one pixel readout to about one row readout.

Among column AD conversion methods, for example, a method called a single slope type is configured to input an analog signal to one input of a comparator and input a reference voltage having a linear relationship with time to the other input. A counter counts the time from the start of comparison to the reversal of the magnitude relationship between the above two inputs and latches the result, thereby outputting a digital signal.

When, however, obtaining a resolution of n bits by using such single slope type column AD conversion, the counter needs to perform counting the nth power of 2 times. This makes it difficult to speed up multi-bit processing. On the other hand, in the above multi-pixel structure or light travel time method, since the number of signals to be read out from a unit pixel increases, it is also difficult to speed up processing.

In a live view (LV) operation which is assumed to use imaging plane AF in a multi-pixel structure or light travel time method, the above two restrictions make it difficult to speed up processing. An increase in frame rate in a live view operation is an important factor in terms of display smoothness, AF speed, accuracy, follow ability, and the like.

### SUMMARY OF INVENTION

The present invention has been made in consideration of the above problem and enables speeding up of imaging plane AF and an readout operation when acquiring distance information in an image capturing apparatus having an arrangement which can output a plurality of signals from a unit pixel.

According to the first aspect of the present invention, there is provided an image capturing apparatus comprising: a plurality of unit pixels arranged in matrix and each including a plurality of photoelectric conversion portions; and an AD converter configured to receive a signal from the unit pixel and operate in one of a first AD conversion mode and a second AD conversion mode different from the first AD conversion mode, wherein the AD converter operates in the first AD conversion mode when being set in a first readout mode of independently outputting signals from the plurality of photoelectric conversion portions, and operates in the second AD conversion mode when being set in a second readout mode of composing and outputting signals from the plurality of photoelectric conversion portions.

According to the second aspect of the present invention, there is provided an image capturing apparatus comprising: a plurality of unit pixels arranged in matrix and each including a photoelectric conversion portion and a plurality of transfer transistors; and an AD converter configured to receive a signal from the unit pixel and operate in one of a first AD conversion mode and a second AD conversion mode different from the first AD conversion mode, wherein the AD converter operates in the first AD conversion mode when being set in a first readout mode of sequentially driving the plurality of transfer transistors and outputting signals from the photoelectric conversion portion, and operates in the second AD conversion mode when being set in a second readout mode of driving any or all of the plurality of transfer transistors at the same time and outputting signals from the photoelectric conversion portion.

According to the third aspect of the present invention, there is provided an image capturing apparatus having a plurality of unit pixels arranged in matrix and each including a plurality of photoelectric conversion portions, comprising: control means for performing control such that a resolution of a pixel signal in a first readout mode of independently outputting signals from the plurality of photoelectric conversion portions is lower than a resolution of a pixel signal in a second readout mode of composing and outputting signals from the plurality of photoelectric conversion portions.

According to the fourth aspect of the present invention, there is provided an image capturing apparatus having a plurality of unit pixels arranged in matrix and each including a plurality of photoelectric conversion portions, comprising: control means for performing control such that a resolution of a pixel signal in a first readout mode of independently outputting signals from the plurality of photoelectric conversion portions is lower than a resolution of a pixel signal in a second readout mode of composing and outputting signals from the plurality of photoelectric conversion portions.

According to the fifth aspect of the present invention, there is provided a method of controlling an image capturing apparatus including a plurality of unit pixels arranged in matrix and each including a plurality of photoelectric conversion portions, comprising an AD conversion step of receiving a signal from the unit pixel and operating in one of a first AD conversion mode and a second AD conversion mode different from the first AD conversion mode, wherein in the AD conversion step, an operation is performed in the first AD conversion mode when setting a first readout mode of independently outputting signals from the plurality of photoelectric conversion portions, and an operation is performed in the second AD conversion mode when setting a second readout mode of composing and outputting signals from the plurality of photoelectric conversion portions.

According to the sixth aspect of the present invention, there is provided a method of controlling an image capturing apparatus including a plurality of unit pixels arranged in matrix and each including a photoelectric conversion portion and a plurality of transfer transistors, comprising an AD conversion step of receiving a signal from the unit pixel and operating in one of a first AD conversion mode and a second AD conversion mode different from the first AD conversion mode, wherein in the AD conversion step, an operation is performed in the first AD conversion mode when setting a first readout mode of sequentially driving the plurality of transfer transistors and outputting signals from the photoelectric conversion portion, and an operation is performed in the second AD conversion mode when setting a second readout mode of driving any or all of the plurality of transfer transistors at the same time and outputting signals from the photoelectric conversion portion.

According to the seventh aspect of the present invention, there is provided a method of controlling an image capturing apparatus including a plurality of unit pixels arranged in matrix and each including a plurality of photoelectric conversion portions, comprising a control step of performing control such that a resolution of a pixel signal in a first readout mode of independently outputting signals from the plurality of photoelectric conversion portions is lower than a resolution of a pixel signal in a second readout mode of composing and outputting signals from the plurality of photoelectric conversion portions.

According to the eighth aspect of the present invention, there is provided a method of controlling an image capturing apparatus including a plurality of unit pixels arranged in matrix and each including a photoelectric conversion portion and a plurality of transfer transistors, comprising a control step of performing control such that a resolution of a pixel signal in a first readout mode of sequentially driving the plurality of transfer transistors and outputting signals from the photoelectric conversion portion is lower than a resolution of a pixel signal in a second readout mode of driving any or all of the plurality of transfer transistors at the same time and outputting signals from the photoelectric conversion portion.

Further features of the present invention will become apparent from the following description of exemplary embodiments with reference to the attached drawings.

### BRIEF DESCRIPTION OF DRAWINGS

FIG. 1 is a block diagram showing the arrangement of an image capturing apparatus according to an embodiment of the present invention;

FIG. 2 is a circuit diagram showing the arrangement of a unit pixel;

FIG. 3 is a timing chart showing the first and second modes according to the first embodiment;

FIG. 4 is a graph showing an example of a reference signal;

FIG. 5 is a flowchart showing an image capture operation according to the first embodiment;

FIG. 6 is a graph for explaining the principle of focus detection;

FIG. 7 is a timing chart showing the first mode according to the second embodiment;

FIG. 8 is a timing chart showing the second mode according to the second embodiment;

FIG. 9 is a flowchart showing an image capture operation according to the second embodiment;

FIG. 10 is a circuit diagram showing the arrangement of a unit pixel according to the third embodiment;

FIG. 11 is a timing chart showing the third mode according to the third embodiment;

FIG. 12 is a timing chart showing the fourth mode according to the third embodiment;

FIG. 13 is a timing chart for explaining the principle of distance measurement according to the third embodiment; and

FIG. 14 is a block diagram of an overall digital camera according to the fourth embodiment.

### DESCRIPTION OF EMBODIMENTS

The embodiments of the present invention will be described in detail below with reference to the accompanying drawings.

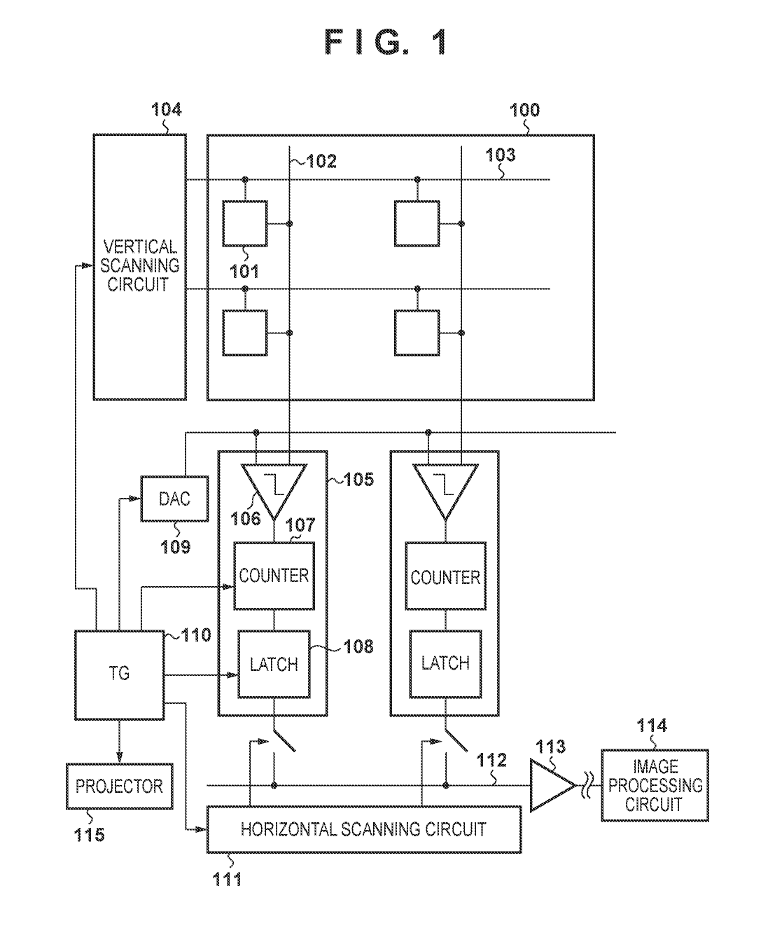

The arrangement of an image capturing apparatus 1100 according to an embodiment of the present invention will be described first with reference to the block diagram of FIG. 1. Referring to FIG. 1, unit pixels 101 are arranged in matrix in a pixel unit 100. Each unit pixel 101 is connected to a vertical signal line (column signal line) 102 via a selection switch (not shown), and outputs an analog signal to a column circuit 105 for each row. In this case, each selection switch performs potential selection control on a specific row from a vertical scanning circuit 104 via a signal line 103. In addition, a timing generator (to be referred to as a TG hereinafter) 110 generates pulse signals which control the vertical scanning circuit 104 and transistors and the like in the unit pixels 101. The TG 110 generates a reference signal (a slope waveform or ramp waveform) via a D/A converter (to be referred to as a DAC hereinafter) 109, and outputs the signal as one signal to a comparator 106. The TG 110 is also connected to a projector 115 to control pulse light emission. The projector 115 is applied to an arrangement described in the third embodiment.

The arrangement of the column circuit 105 will be described next. Each column circuit 105 is constituted by the comparator 106, a counter 107, and a latch 108. Each vertical signal line 102 is connected to the other input of the corresponding comparator 106. Each comparator 106 compares a potential VI of the corresponding vertical signal line 102 with a reference signal which changes with time, and detects the time until the magnitude relationship between them is reversed. Each counter 107 measures the time until the magnitude relationship between them is reversed, based on clocks, and obtains the measurement time as a digital signal. The corresponding latch 108 holds the digital signal measured by the counter 107.

A horizontal scanning circuit 111 sequentially scans the column circuits in the column direction and outputs digital signals held in the latches 108 via a horizontal signal line 112 and an output terminal 113 commonly connected to the column circuits for each column. The horizontal scanning circuit 111 is also controlled by the TG 110. An image processing circuit 114 on the subsequent stage performs predetermined processing for the output digital signals.

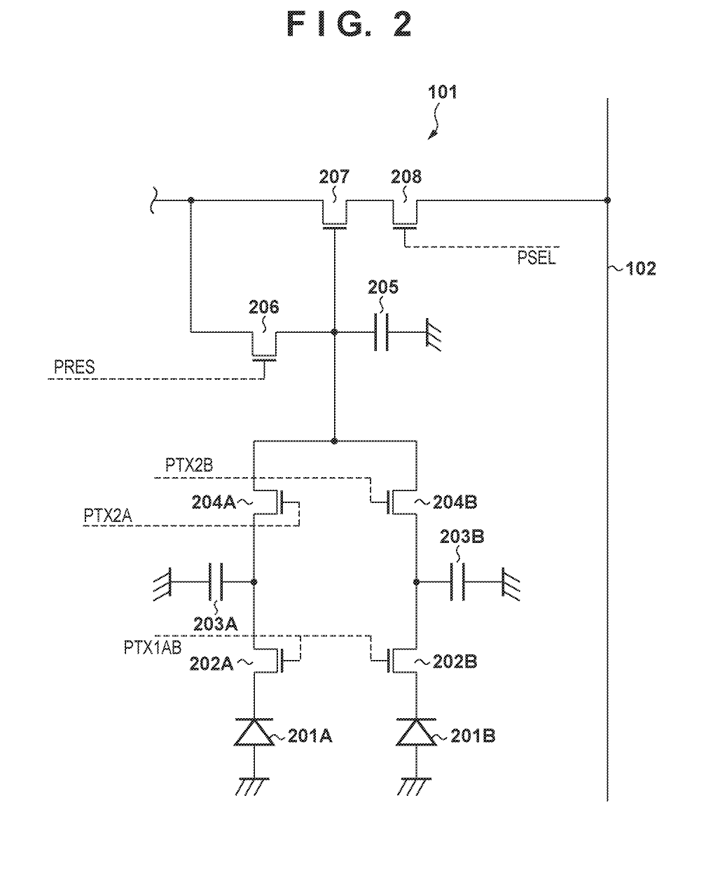

FIG. 2 is a circuit diagram showing an example of the arrangement of each unit pixel 101 in this embodiment. Each unit pixel 101 includes a PD 201A and a PD 201B which are first and second PDs (photodiodes). These two PDs have almost the same sensitivity and are arranged to share one microlens (not shown), thereby forming a multi-pixel structure capable of detecting a phase difference. In this embodiment, an image signal from a pixel on the first PD 201A side is defined as an A image signal, and an image signal from a pixel on the second PD 201B side is defined as a B image signal.

The PD 201A is connected to a pixel memory 203A via a first transfer switch (transfer transistor) 202A. The PD 201B is connected to a pixel memory 203B via a first transfer switch 202B. In this case, both the first transfer switches 202A and 202B are controlled by a transfer pulse PTX1AB.

The pixel memory 203A is connected to an FD (Floating Diffusion unit) 205 via a second transfer switch 204A. The pixel memory 203B is connected to the FD 205 via a second transfer switch 204B. In this case, the second transfer switch 204A is controlled by a transfer pulse PTX2A. The second transfer switch 204B is controlled by a transfer pulse PTX2B.

A reset switch 206 is controlled by a reset pulse PRES to supply a reference potential VDD to the FD 205. A pixel amplifier 207 is a source follower circuit constituted by a MOS transistor and the reference potential VDD. A selection switch 208 is controlled by a selection pulse PSEL to output a potential variation of the pixel amplifier 207 from the vertical signal line 102 to the corresponding column circuit.

### First Embodiment

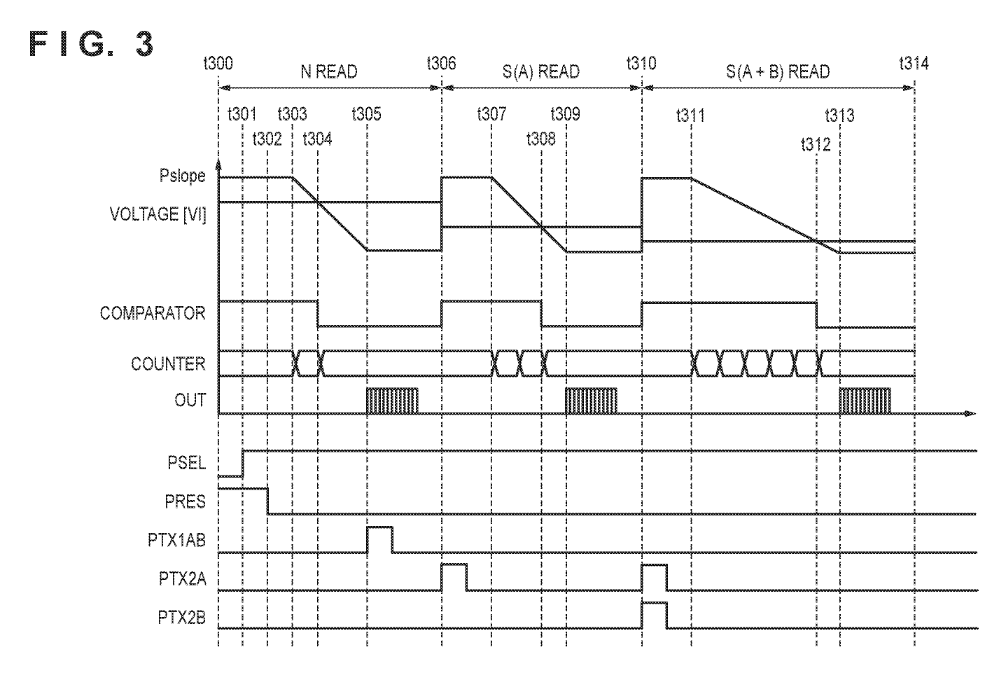

An image capturing apparatus according to the first embodiment has a first signal readout mode of acquiring independent signals from a plurality of PDs and a second signal readout mode of acquiring a composite signal from the plurality of PDs. FIG. 3 is a timing chart showing the readout operation and AD conversion operation of the image capturing apparatus according to the first embodiment, and indicates a control pulse, vertical signal line potential, reference signal, and count value when reading out a given row.

Referring to FIG. 3, a comparator 106 receives reference signals Pslope1 and Pslope2 having different slopes in accordance with the first and second signal readout modes.

At time t301, a given row is connected to a vertical signal line 102 by a selection pulse PSEL. An FD 205 is reset by a reset pulse PRES by time t302. Subsequently, in the interval from time t303 to time t306, a reset signal N is AD-converted. When the magnitude relationship between a potential VI of the vertical signal line 102 and the reference signal Pslope1 is reversed at time t304, the counter stops and holds the count value at that moment. Thereafter, the reference signal Pslope1 makes a transition until it reaches a predetermined upper limit value, and “N read” is complete at time t305. Then, up to time t306, counter values are sequentially scanned in the column direction, and an image processing circuit 114 performs predetermined processing. In parallel with this operation, the charges of the PD are transferred to the corresponding pixel memory by a transfer pulse PTX1AB.

At time t306, the charges in a pixel memory 203A are transferred to an FD 205, the potential VI of the vertical signal line 102 becomes a potential corresponding to a pixel signal, and the comparator 106 is reset. In the interval from time t307 to time t310, a pixel signal S(A) is AD-converted (the first AD conversion mode). When the magnitude relationship between the potential VI of the vertical signal line 102 and the reference signal Pslope1 is reversed at time t308, the counter stops and holds the count value at that moment. Thereafter, the reference signal Pslope1 makes a transition until it reaches a predetermined upper limit value, and “S(A) read” is complete at time t309. Then, up to time t310, counter values are sequentially scanned in the column direction, and the image processing circuit 114 performs predetermined processing.

Subsequently, when charges in the pixel memory 203A and a pixel memory 203B are transferred to the FD 205 at time t310, the potential VI of the vertical signal line 102 becomes a potential corresponding to a pixel signal, and the comparator 106 is reset. Subsequently, in the interval from time t311 to time t314, a pixel signal S(A+B) is AD-converted (the second AD conversion mode). When the magnitude relationship between the potential VI of the vertical signal line 102 and the reference signal Pslope2 is reversed at time t312, the counter stops and holds the count value at that moment. Thereafter, the reference signal Pslope2 makes a transition until it reaches a predetermined upper limit value, and “S(A+B) read” is complete at time t313. Then, up to time t314, counter values are sequentially scanned in the column direction, and the image processing circuit 114 performs predetermined processing.

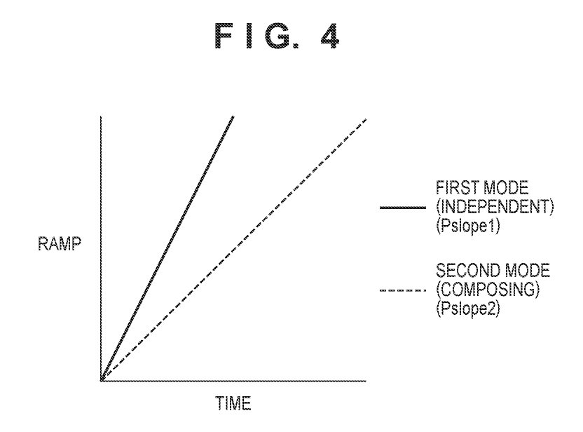

FIG. 4 is a graph showing the time dependence of this reference signal. In the first embodiment, in the first signal readout mode, a reference signal (Pslope1) with a slope waveform having the first slope with respect to the time is referred to. On the other hand, in the second signal readout mode, a reference signal (Pslope2) with a slope waveform having a slope ½ the first slope with respect to the time is referred to. As a method of generating reference signals with different slope waveforms, a known method, for example, a method of changing a constant current value and a resistance value in a DAC 109, is used. In addition, the reset signal N is configured to refer to the reference signal Pslope1.

For example, the image processing circuit 114 performs the following processing for the reset signal N, the pixel signal S(A), and the pixel signal S(A+B).

image capture: S(A+B)−N×2=S(g) (1)

distance measurement A: S(A)−N=S(a) (2)

distance measurement B: S(A+B)/2−S(A)=S(b) (3)

A captured image is generated by the signal obtained from equation (1). Focus detection or distance measurement is performed based on the signals obtained from equations (2) and (3). In addition, it is obvious from equations (1) to (3) that the image capture resolution is higher than the distance measurement information.

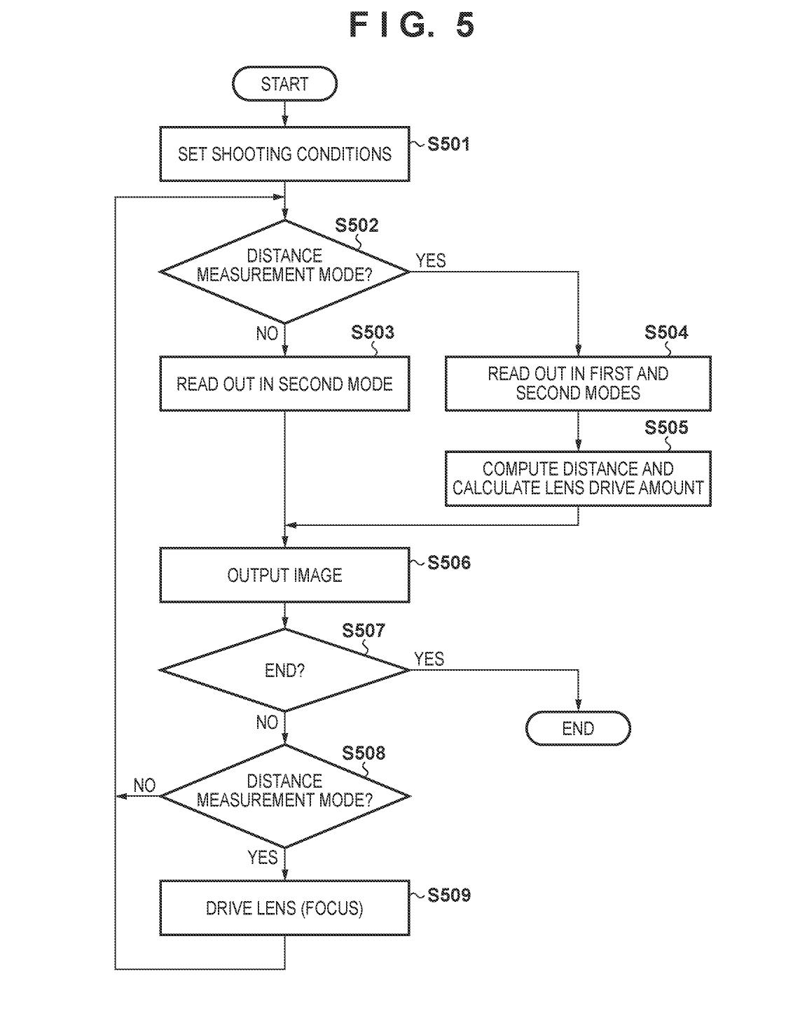

FIG. 5 is a flowchart for explaining a procedure for an image capture operation according to the first embodiment. Referring to FIG. 5, in step S501, the user sets a shooting mode such as a still image or moving image shooting mode and shooting conditions such as AF and sensitivity. Alternatively, the image capturing apparatus automatically makes such settings.

In step S502, it is determined whether the set mode is the shooting mode of executing imaging plane phase difference AF. If the set mode is the shooting mode of not executing imaging plane phase difference AF, the process advances to step S503. If the set mode is the shooting mode of executing imaging plane phase difference AF, the process advances to step S504.

In step S503, a composite signal is obtained from a plurality of PDs in the second signal readout mode. In step S504, independent signals are acquired from a plurality of PDs in the first signal readout mode, and a composite signal is acquired from the plurality of PDs in the second signal readout mode.

In step S505, the focal position of an object and a lens drive amount for focusing are calculated from AD-converted signal outputs. In step S506, an image signal is output to a display circuit and a recording circuit such as a memory card.

In step S507, it is determined whether shooting is finished. If shooting is to be continued, the process advances to step S508 to perform focus driving and acquire signals again. If shooting is to be finished, the series of operations is terminated.

In step S508, shooting mode setting in the image capturing apparatus is determined again. In this case, if the set mode is the shooting mode of not executing imaging plane phase difference AF, the process returns to step S502 to repeat the above operation. In this case, the process can return to step S501 to re-set AF, sensitivity, and the like. On the other hand, if the set mode is the shooting mode of executing imaging plane AF, the process advances to step S509.

In step S509, the lens (focus) is actually driven in accordance with the lens drive amount calculated in step S505. The process then returns to step S502 to repeat the above operation. In this case, the process can return to step S501 to re-set AF, sensitivity, and the like.

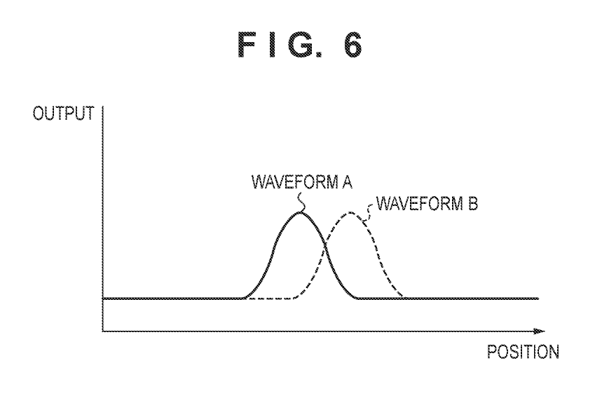

For reference, the principle of focus detection by a pupil division method in this embodiment will be described below with reference to FIG. 6. As described with reference to FIG. 2, a PD 201A and a PD 201B have received light from different regions of the exit pupil of the imaging lens. A plurality of unit pixels 101 arranged in the baseline length direction acquire signals (A image signals) from the PD 201A having undergone pupil division. An object image formed from these output signals is defined as waveform A. Likewise, a plurality of unit pixels 101 arranged in the baseline length direction acquire signals (B image signals) from the PD 201B having undergone pupil division. An object image formed from these output signals is defined as waveform B.

Correlation computation is executed for waveforms A and B to detect an image shift amount. In addition, multiplying the image shift amount by a conversion coefficient determined from an optical system can calculate the focal position of the object. It is possible to perform imaging plane AF by controlling the focus of the imaging lens based on the calculated focal position information.

In addition, adding the A image signal and the B mage signal to obtain an (A+B) image signal makes it possible to use the resultant signal as a normal shot image without any phase difference.

Note that since the first embodiment is configured to read out an A image signal and an (A+B) image signal, the latter can be directly used as a shot image. In addition, the image processing circuit on the subsequent stage generates a B image signal by subtracting the A image signal from the (A+B) image signal.

As described above, the image capturing apparatus according to the first embodiment is configured to change settings in the column AD converter in accordance with a case in which signals generated by a plurality of photoelectric conversion portions are independently read out (the first signal readout mode) and a case in which the signals are read out upon addition by FDs (the second signal readout mode). According to the scope of this embodiment, in the normal shooting mode of not executing imaging plane phase difference AF, accuracy is obtained over the AD conversion time, whereas in the mode of acquiring a distance measurement signal by executing imaging plane phase difference AF, the AD conversion time is shortened.

Although the pixel memories are used in the pixel arrangement, they are not essential elements to achieve the above object. In addition, a plurality of vertical signal lines 102 may be formed in correspondence with a plurality of photoelectric conversion portions.

### Second Embodiment

The second embodiment is a modification of the first embodiment. In the first signal readout mode of acquiring independent signals from the plurality of PDs described above, both an A image signal and a B image signal are separately acquired. In the second signal readout mode of acquiring a composite signal from a plurality of PDs, an (A+B) image signal is acquired as in the first embodiment. Since the arrangement of a unit pixel 101 is the same as that shown in FIG. 2, a description of the arrangement will be omitted.

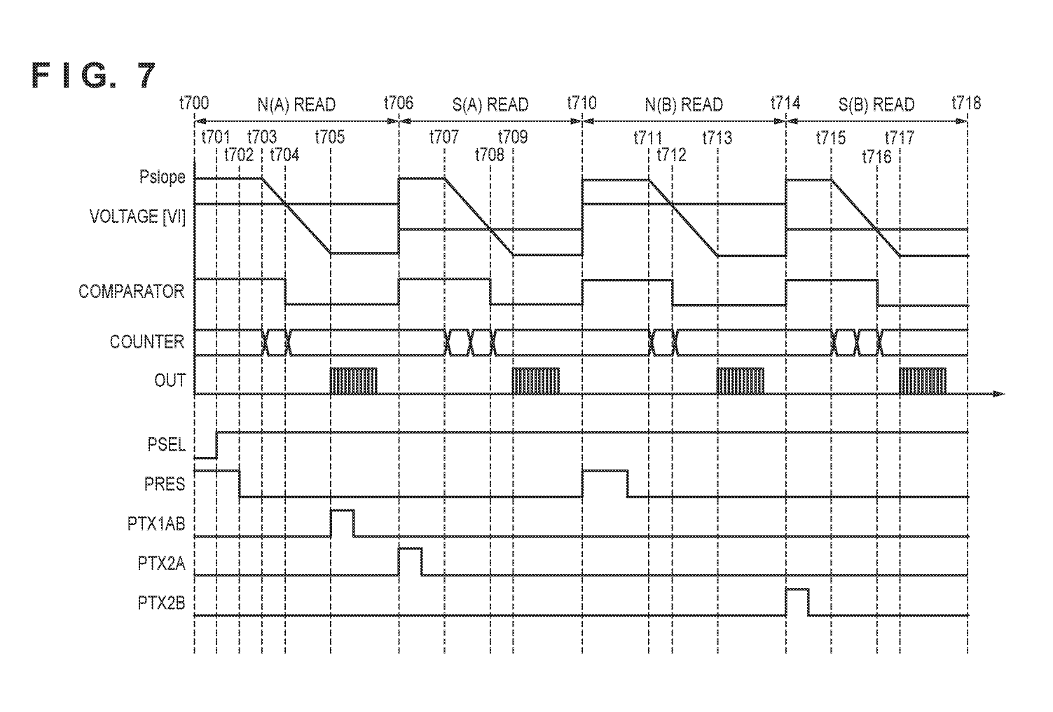

FIG. 7 is a timing chart in the first signal readout mode according to the second embodiment. Referring to FIG. 7, a comparator 106 receives a reference signal Pslope1 corresponding to the first signal readout mode.

At time t701, a given row is connected to a vertical signal line 102 by a selection pulse PSEL. An FD 205 is reset by a reset pulse PRES by time t702. Subsequently, in the interval from time t703 to time t706, a reset signal N(A) is AD-converted. Thereafter, the reference signal Pslope1 makes a transition until it reaches a predetermined upper limit value, and “N(A) read” is complete at time t705. Then, up to time t706, counter values are sequentially scanned in the column direction, and an image processing circuit 114 performs predetermined processing. In parallel with this operation, the charges of the PD are transferred to the corresponding pixel memory by a transfer pulse PTX1AB.

At time t706, the charges in a pixel memory 203A are transferred to the FD 205, a potential VI of the vertical signal line 102 becomes a potential corresponding to a pixel signal, and the comparator 106 is reset. Subsequently, in the interval from time t707 to time t710, a pixel signal S(A) is AD-converted (the first AD conversion mode). Thereafter, the reference signal Pslope1 makes a transition until it reaches a predetermined upper limit value, and “S(A) read” is complete at time t709. Then, up to time t710, counter values are sequentially scanned in the column direction, and the image processing circuit 114 performs predetermined processing.

In addition, at time t710, the FD 205 is reset by the reset pulse PRES, the potential VI of the vertical signal line 102 becomes a potential corresponding to a reset signal, and the comparator 106 is reset. Subsequently, in the interval from time t711 to time t714, a reset signal N(B) is AD-converted. Thereafter, the reference signal Pslope1 makes a transition until it reaches a predetermined upper limit value, and “N(B) read” is complete at time t713. Then, up to time t714, counter values are sequentially scanned in the column direction, and the image processing circuit 114 performs predetermined processing.

At time t714, the charges in the pixel memory 203B are transferred to an FD 205, the potential VI of the vertical signal line 102 becomes a potential corresponding to a pixel signal, and the comparator 106 is reset. Subsequently, in the interval from time t715 to time t718, a pixel signal S(B) is AD-converted (the first AD conversion mode). Thereafter, the reference signal Pslope1 makes a transition until it reaches a predetermined upper limit value, and “S(B) read” is complete at time t717. Then, up to time t718, counter values are sequentially scanned in the column direction, and the image processing circuit 114 performs predetermined processing.

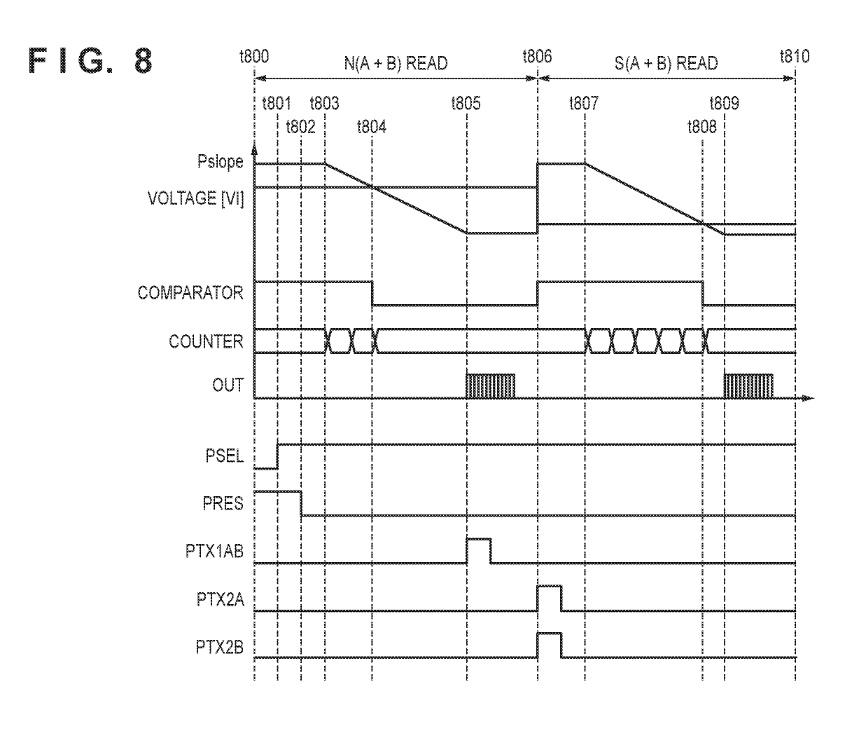

FIG. 8 is a timing chart in the second signal readout mode according to the second embodiment. Referring to FIG. 8, the comparator 106 receives a reference signal Pslope2 corresponding to the second signal readout mode.

At time t801, a given row is connected to the vertical signal line 102 by the selection pulse PSEL. The FD 205 is reset by the reset pulse PRES by time t802. Subsequently, in the interval from time t803 to time t806, a reset signal N(A+B) is AD-converted. Thereafter, the reference signal Pslope2 makes a transition until it reaches a predetermined upper limit value, and “N(A+B) read” is complete at time t805. Then, up to time t806, counter values are sequentially scanned in the column direction, and an image processing circuit 114 performs predetermined processing. In parallel with this operation, the charges of the PD are transferred to the corresponding pixel memory by the transfer pulse PTX1AB.

At time t806, the charges in the pixel memories 203A and 203B are transferred to the FD 205, the potential VI of the vertical signal line 102 becomes a potential corresponding to a pixel signal, and the comparator 106 is reset. Subsequently, in the interval from time t807 to time t810, a pixel signal S(A+B) is AD-converted (the second AD conversion mode). Thereafter, the reference signal Pslope2 makes a transition until it reaches a predetermined upper limit value, and “S(A+B) read” is complete at time t809. Then, up to time t810, counter values are sequentially scanned in the column direction, and the image processing circuit 114 performs predetermined processing.

For example, the image processing circuit 114 performs the following processing for the reset signals N(A), N(B), and N(A+B), and the pixel signals S(A), S(B), and S(A+B).

image capture: S(A+B)−N(A+B)=S(g) (4)

distance measurement A: S(A)−N(A)=S(a) (5)

distance measurement B: S(B)−N(B)=S(b) (6)

A captured image is generated by the signal obtained from equation (4). Focus detection or distance measurement is performed based on the signals obtained from equations (5) and (6). In addition, a captured image may be generated by adding equations (5) and (6).

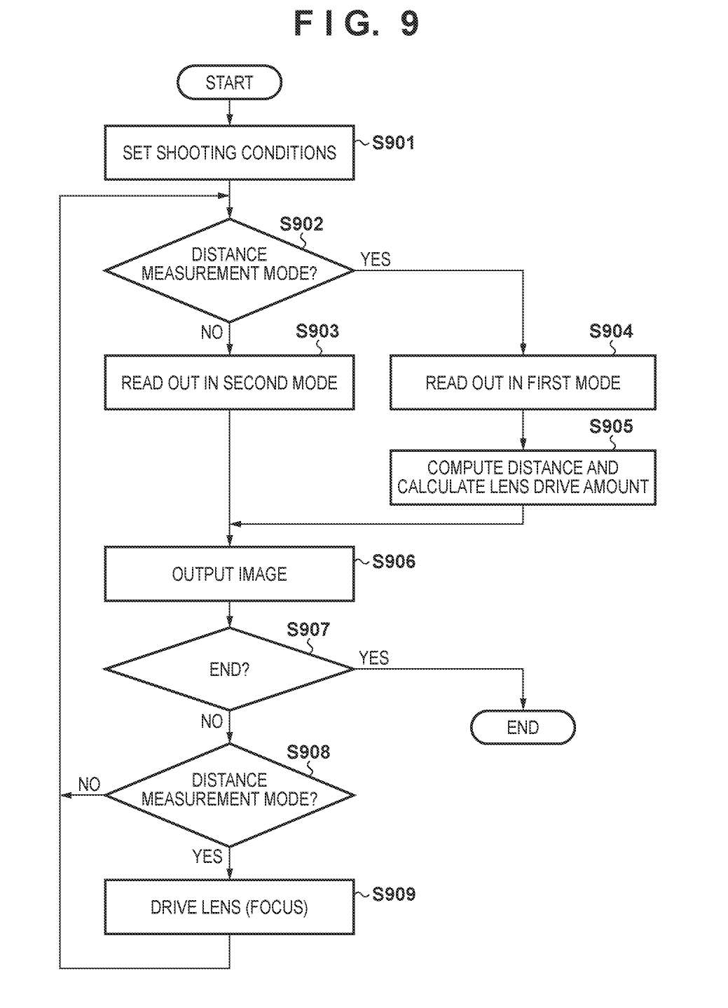

FIG. 9 is a flowchart for explaining a procedure for an image capture operation according to the second embodiment. The second embodiment is configured to perform a readout operation in step S504 only in the first signal readout mode described with reference to FIG. 5.

Referring to FIG. 9, in step S901, the user sets a shooting mode such as a still image or moving image shooting mode and shooting conditions such as AF and sensitivity. Alternatively, the image capturing apparatus automatically makes such settings.

In step S902, it is determined whether the set mode is the shooting mode of executing imaging plane phase difference AF. If the set mode is the shooting mode of not executing imaging plane phase difference AF, the process advances to step S903. If the set mode is the shooting mode of executing imaging plane phase difference AF, the process advances to step S904.

In step S903, a composite signal is obtained from a plurality of PDs in the second signal readout mode. In step S904, independent signals are acquired from a plurality of PDs in the first signal readout mode. In step S905, the focal position of an object and a lens drive amount for focusing are calculated from AD-converted signal outputs.

In step S906, an image signal is output to a display circuit and a recording circuit such as a memory card. In step S907, it is determined whether shooting is finished. If shooting is to be continued, the process advances to step S908 to perform focus driving and acquire signals again. If shooting is to be finished, the series of operations is terminated.

In step S908, shooting mode setting in the image capturing apparatus is determined again. In this case, if the set mode is the shooting mode of not executing imaging plane phase difference AF, the process returns to step S902 to repeat the above operation. In this case, the process can return to step S901 to re-set AF, sensitivity, and the like. On the other hand, if the set mode is the shooting mode of executing imaging plane AF, the process advances to step S909.

In step S909, the lens (focus) is actually driven in accordance with the lens drive amount calculated in step S905. The process then returns to step S902 to repeat the above operation. In this case, the process can return to step S901 to re-set AF, sensitivity, and the like.

The first embodiment is configured to generate a B image signal by subtracting an A image signal from an (A+B) image signal. In contrast to this, the second embodiment is configured to independently acquire an A image signal and a B image signal to allow them to be directly used for focus detection. In this arrangement, it is possible to use an (A+B) image as a shot image by adding an A image signal and a B image signal in the image processing circuit on the subsequent stage.

As described above, in the first and second embodiments, signals generated by a plurality of photoelectric conversion portions are independently read out by using a slope waveform with ½ resolution. This is because, even with a low resolution, it is possible to satisfy required accuracy by correlation computation. In addition, although the resolution of each of an A image signal and a B image signal becomes ½, it is possible to satisfy the accuracy required as an (A+B) image signal used for the generation of an image in an addition process.

### Third Embodiment

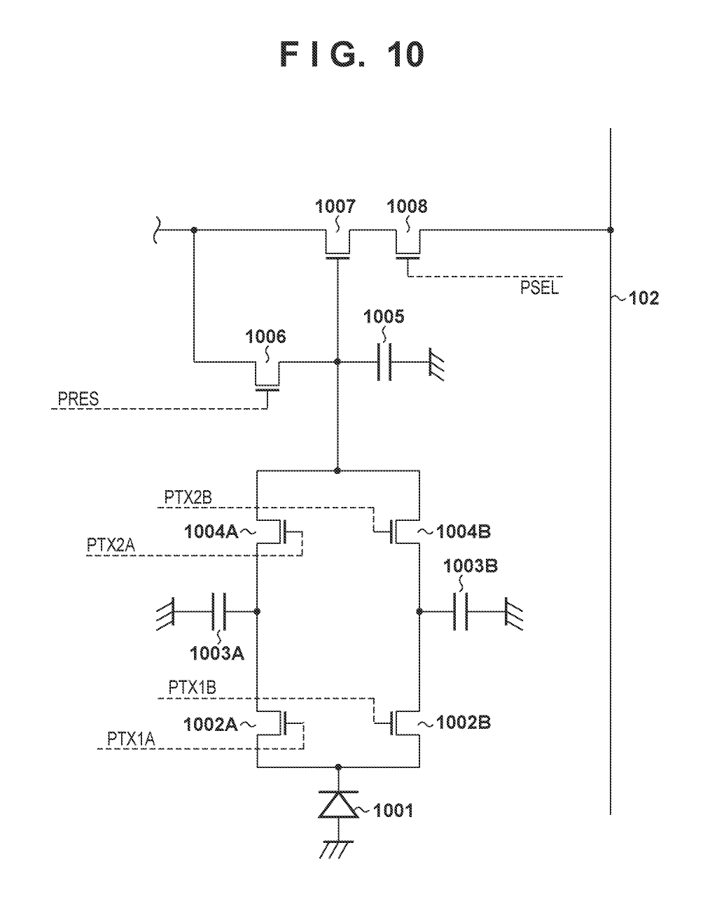

FIG. 10 is a circuit diagram showing an example of the arrangement of a unit pixel 101 according to the third embodiment. The arrangement of the unit pixel 101 according to the third embodiment differs from that described above in that it includes one PD 1001.

The PD 1001 is connected to a pixel memory 1003A via a first transfer switch 1002A, and is connected to a pixel memory 1003B via a first transfer switch 1002B. This PD has two transfer switches connected thereto to allow the use of the so-called time travel time method. In this case, the first transfer switch 1002A is controlled by a transfer pulse PTX1A. The first transfer switch 1002B is controlled by a transfer pulse PTX1B. In this embodiment, a signal on the first transfer switch 1002A side is defined as an A signal, and an image signal on the first transfer switch 1002B side is defined as a B signal.

In addition, the pixel memory 1003A is connected to a shared FD 1005 via a second transfer switch 1004A, and the pixel memory 1003B is also connected to the FD 1005 via a second transfer switch 1004B. In this case, the second transfer switch 1004A is controlled by a transfer pulse PTX2A, and the second transfer switch 1004B is controlled by a transfer pulse PTX2B.

A reset switch 1006 is controlled by a reset pulse PRES to supply a reference potential VDD to the FD 1005. A pixel amplifier 1007 is a source follower circuit constituted by a MOS transistor and the reference potential VDD. A selection switch 1008 is controlled by a selection pulse PSEL to output a potential variation of the pixel amplifier 1007 from a vertical signal line 102 to a column circuit.

As shown in FIG. 1, the image capturing apparatus according to the third embodiment includes a projector 115 which projects pulse light originating from infrared radiation or the like onto an object. The projector 115 is controlled by a projection pulse PLIGHT.

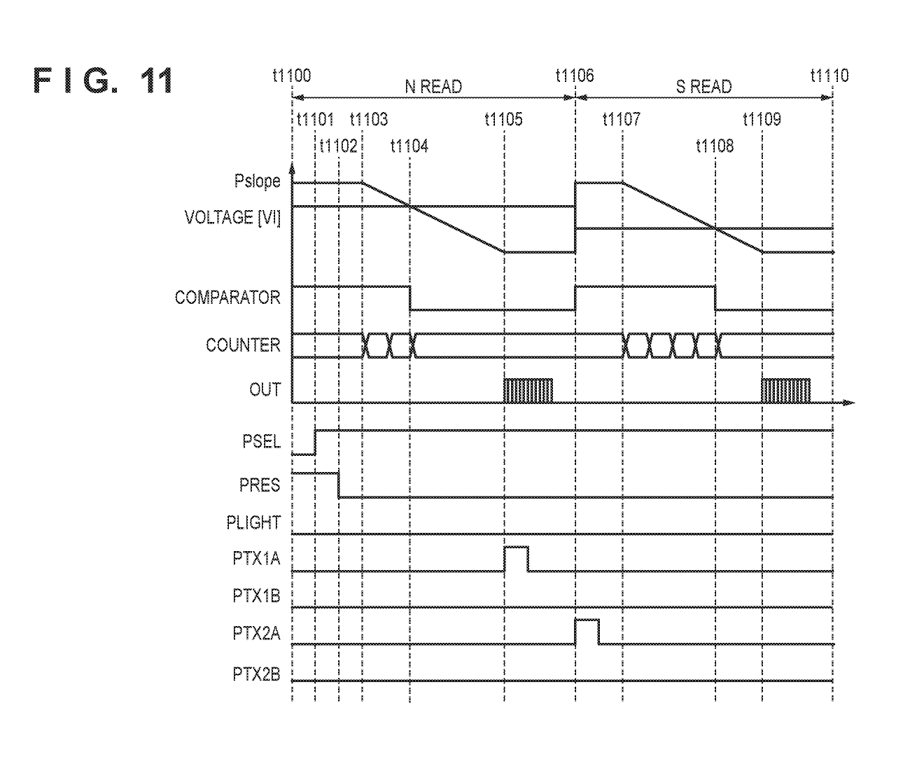

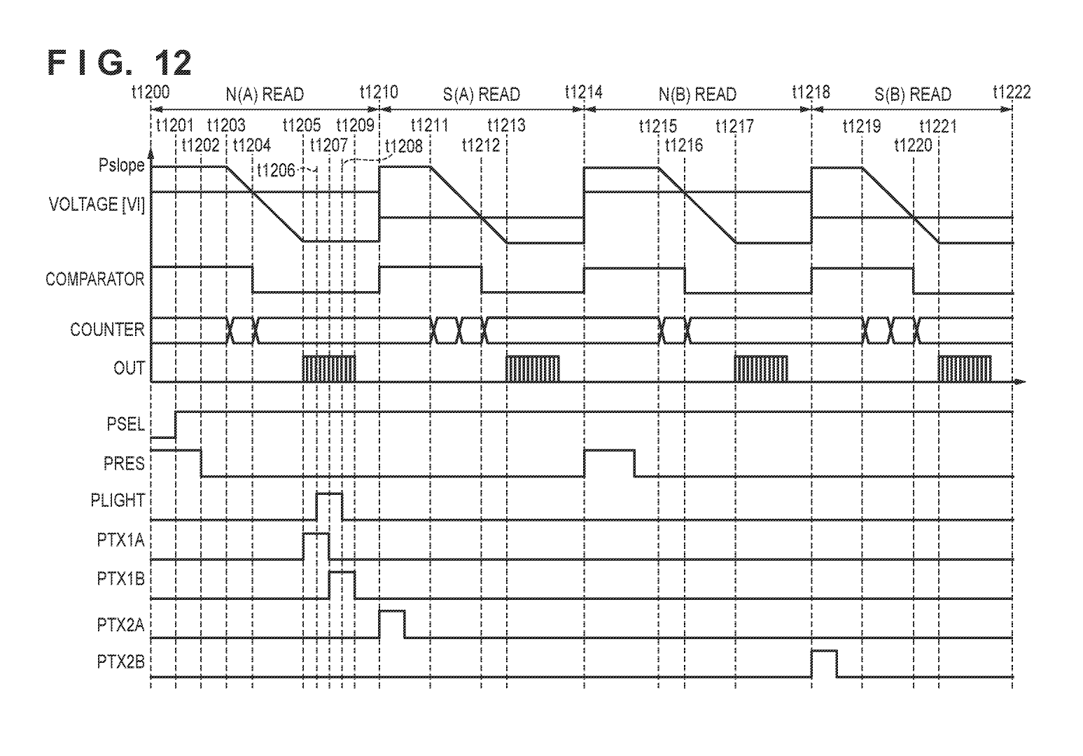

The image capturing apparatus according to the third embodiment has the third signal readout mode of acquiring one signal from one PD and the fourth signal readout mode of acquiring a plurality of signals from one PD. FIGS. 11 and 12 are timing charts showing the readout operation and AD conversion operation of the image capturing apparatus according to the third embodiment, and show a control pulse, vertical signal line potential, reference signal, and count value when reading out a given row.

First of all, FIG. 11 shows a timing chart at the time of the third signal readout mode. Referring to FIG. 11, a comparator 106 receives a reference signal Pslope2 described in the first embodiment.

At time t1101, a given row is connected to the vertical signal line 102 by the selection pulse PSEL. The FD 1005 is reset by the reset pulse PRES by time t1102. Subsequently, in the interval from time t1103 to time t1106, a reset signal N is AD-converted. Thereafter, the reference signal Pslope2 makes a transition until it reaches a predetermined upper limit value, and “N read” is complete at time t1105. Then, up to time t1106, counter values are sequentially scanned in the column direction, and an image processing circuit 114 performs predetermined processing. In parallel with this operation, the charges of the PD are transferred to the corresponding pixel memory by the transfer pulse PTX1A.

At time t1106, the charges in the pixel memory 1003A are transferred to the FD 1005, a potential VI of the vertical signal line 102 becomes a potential corresponding to a pixel signal, and the comparator 106 is reset. Subsequently, in the interval from time t1107 to time t1110, a pixel signal S is AD-converted (the second AD conversion mode). Thereafter, the reference signal Pslope2 makes a transition until it reaches a predetermined upper limit value, and “S read” is complete at time t1109. Then, up to time t1110, counter values are sequentially scanned in the column direction, and the image processing circuit 114 performs predetermined processing.

As described above, in the third signal readout mode, the signal generated by each photoelectric conversion portion is output as one pixel signal per unit pixel by using one transfer switch. This mode is applied to a case in which a normal still image or moving image is acquired without performing the light travel time method.

Note that the above description has exemplified the case in which in the third signal readout mode, the charges generated in the PD 1001 are transferred to the pixel memory 1003A via the first transfer switch 1002A, and are further transferred to the FD 1005 via the second transfer switch 1004A. However, the present invention is not limited to this.

That is, in the third signal readout mode, the charges generated in the PD 1001 are transferred to the pixel memory 1003A via the first transfer switch 1002A, and are simultaneously transferred to the pixel memory 1003B via the first transfer switch 1002B. In addition, the charges held in the pixel memory 1003A may be transferred to the FD 1005 via the second transfer switch 1004A, and at the same time, the charges held in the pixel memory 1003B may be transferred to the FD 1005 via the second transfer switch 1004B.

FIG. 12 shows a timing chart at the time of the fourth signal readout mode. Referring to FIG. 12, the comparator 106 receives the reference signal Pslope1 described in the first embodiment.

At time t1201, a given row is connected to the vertical signal line 102 by the selection pulse PSEL. The FD 1005 is reset by the reset pulse PRES by time t1202.

Subsequently, in the interval from time t1203 to time t1210, a reset signal N(A) is AD-converted. Thereafter, the reference signal Pslope1 makes a transition until it reaches a predetermined upper limit value, and “N(A) read” is complete at time t1205. Then, up to time t1210, counter values are sequentially scanned in the column direction, and an image processing circuit 114 performs predetermined processing.

In parallel with this operation, light travel time distance measurement is executed. At time t1205, the transfer pulse PTX1A is set at Hi, and the light charges accumulated in the PD 1001 begin to be transferred to the pixel memory 1003A. Thereafter, the projection pulse PLIGHT is set at Hi at time t1206 to start light projection. At time t1207, the transfer pulse PTX1A is set at Lo, and at the same time, the transfer pulse PTX1B is set at Hi, thereby starting to transfer the light charges accumulated in the PD 1001 to the pixel memory 1003B. The projection pulse PLIGHT is set at Lo at time t1208 to finish light projection. The transfer pulse PTX1B is set at Lo at time t1209 to finish the transfer.

Subsequently, at time t1210, the charges in the pixel memory 1003A are transferred to the FD 1005, the potential VI of the vertical signal line 102 becomes a potential corresponding to a pixel signal, and the comparator 106 is reset. Subsequently, in the interval from time t1211 to time t1214, a pixel signal S(A) is AD-converted (the first AD conversion mode). Thereafter, the reference signal Pslope1 makes a transition until it reaches a predetermined upper limit value, and “S(A) read” is complete at time t1213. Then, up to time t1214, counter values are sequentially scanned in the column direction, and the image processing circuit 114 performs predetermined processing.

At time t1214, the FD 1005 is reset by the reset pulse PRES, the potential VI of the vertical signal line 102 becomes a potential corresponding to a reset signal, and the comparator 106 is reset. Subsequently, in the interval from time t1215 to time t1218, a reset signal N(B) is AD-converted. Thereafter, the reference signal Pslope1 makes a transition until it reaches a predetermined upper limit value, and “N(B) read” is complete at time t1217. Then, up to time t1218, counter values are sequentially scanned in the column direction, and the image processing circuit 114 performs predetermined processing.

At time t1218, the charges in the pixel memory 1003B are transferred to an FD 1005, the potential VI of the vertical signal line 102 becomes a potential corresponding to a pixel signal, and the comparator 106 is reset. Subsequently, in the interval from time t1219 to time t1222, a pixel signal S(B) is AD-converted (the first AD conversion mode). Thereafter, the reference signal Pslope1 makes a transition until it reaches a predetermined upper limit value, and “S(B) read” is complete at time t1221. Then, up to time t1222, counter values are sequentially scanned in the column direction, and the image processing circuit 114 performs predetermined processing.

As described above, in the fourth signal readout mode, the signals generated by each photoelectric conversion portion are read out in a time-series manner by using two transfer switches, thereby outputting the resultant signals as a plurality of time-division signals. This mode is applied to a case in which distance measurement information is acquired by the light travel time method.

For example, the image processing circuit 114 performs the following processing for the reset signals N(A), N(B), and N and the pixel signals S(A), S(B), and S.

image capture: S−N=S(g) (7)

distance measurement A: S(A)−N(A)=S(a) (8)

distance measurement B: S(B)−N(B)=S(b) (9)

A captured image is generated from the signal obtained from equation (7), and focus detection or distance measurement is performed based on the signals obtained from equations (8) and (9).

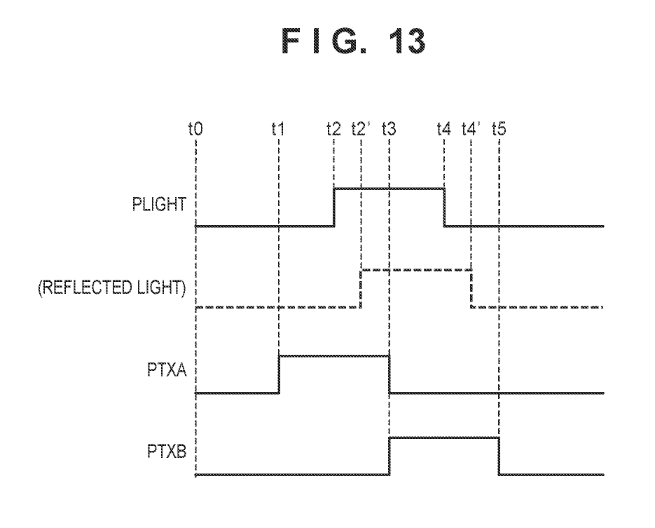

For reference, the principle of light travel time distance measurement in this embodiment will be described with reference to FIG. 13. In this case, the two transfer switches connected to one PD are sequentially driven in synchronism with the projection of pulse light. Referring to FIG. 13, the pulse PLIGHT is a projection pulse from the projector 115 in FIG. 1. The pulses PTXA and PTXB correspond to the transfer pulses PTX1A and PTX1B for the first transfer switches 1002A and 1002B in FIG. 10.

For example, the pulse PTXA is set at Hi at time t1. The pulse PTXB is set at Hi at the same time when the pulse PTXA is set at Lo at time t3, and is set at Lo at time t5. In this case, the Hi periods of the two signals are equal to each other, and pulse light is projected by the projection pulses PLIGHT at times t2 and t4 during the Hi periods of the respective pulses.

If the distance to an object is 0, reflected light is received at the same time with the projection pulse PLIGHT. In addition, when times t2 and t4 are set between times t1 and t3 and between times t3 and t5, respectively, identical signals are output as the pulses PTXA and PTXB. If the distance to the object is not 0, reflected light is received with a delay of (t2′−t2), as shown in FIG. 13. As a result, in the Hi period of the pulse PTXA, a signal corresponding to (t3−t2′) is received, whereas in the Hi period of the pulse PTXB, a signal corresponding to (t4′−t3) is received, resulting in signals having a deviation. The delay time of reflected light from projection light can be estimated from the ratio of these signals. It is possible to calculate the distance to the object from the product of the delay time and the light velocity. For example, as described above, if times t2 and t4 are set between times t1 and t3 and between times t3 and t5, respectively, a distance L to the object is represented by L=((t4−t2)c/4)(2R−1) where c is the light velocity. In this case, R represents the ratio of charges QB transferred by PTXB to the total charges, and is given as R=QB/(QA+QB)=(t4′−t3)/(t4′−t2′).

As described above, the third embodiment is also configured to change settings in the column AD converter in accordance with a case in which the signal generated by each photoelectric conversion portion is read out as a single signal per unit pixel and a case in which the signal is read out upon being divided into a plurality of signals.

### Fourth Embodiment

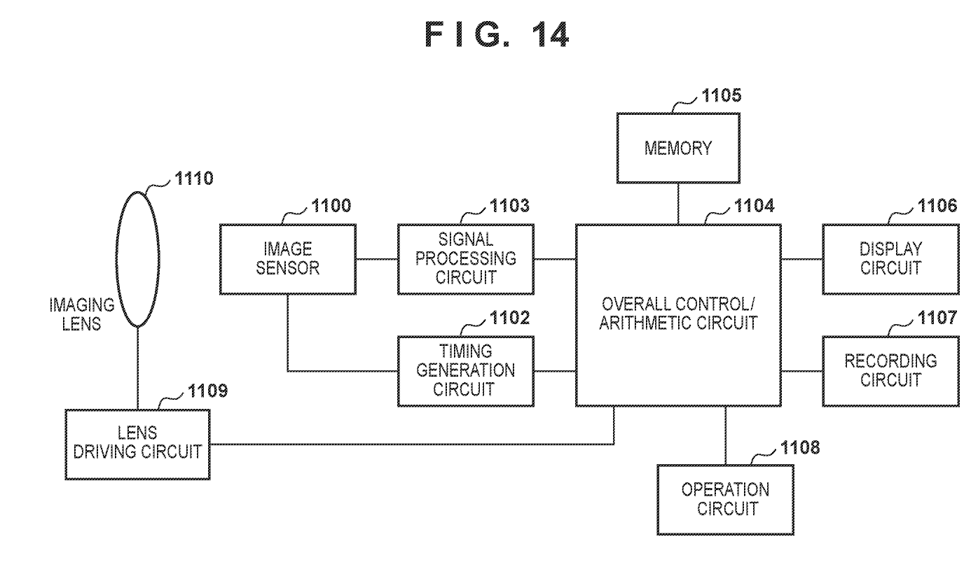

An embodiment in which the image capturing apparatus 1100 described in the first to third embodiments is applied to a digital camera will be described below. FIG. 14 is a block diagram showing an overall digital camera according to the fourth embodiment of the present invention.

A lens driving circuit 1109 performs zoom control, focus control, stop control, and the like on an imaging lens 1110 to form an optical image of an object on the image capturing apparatus. The image capturing apparatus 1100 has the arrangement described in the first to third embodiments. The image capturing apparatus 1100 converts the object image formed by the imaging lens 1110 into an image signal and outputs it.

A signal processing circuit 1103 performs various types of correction processing and data compression processing with respect to image signals output from the image capturing apparatus 1100. A timing generation circuit 1102 supplies various types of drive timing signals to the image capturing apparatus 1100. An overall control/arithmetic circuit 1104 controls the overall digital camera as well as performing various types of arithmetic processing.

A memory 1105 temporarily stores image data and the like. A display circuit 1106 displays various types of information and a shot image. A detachable recording circuit 1107 such as a semiconductor memory records image data. An operation circuit 1108 electrically receives the operation of an operation member by the operator.

### OTHER EMBODIMENTS

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application Nos. 2014-021703, filed Feb. 6, 2014 and 2014-231974, filed Nov. 14, 2014, which are hereby incorporated by reference herein in their entirety.

1. An image capturing apparatus comprising:
a plurality of unit pixels arranged in matrix and each including a plurality of photoelectric conversion portions; and
an AD converter configured to receive a signal from the unit pixel and operate in one of a first AD conversion mode and a second AD conversion mode different from the first AD conversion mode,
wherein the AD converter operates in the first AD conversion mode when being set in a first readout mode of independently outputting signals from the plurality of photoelectric conversion portions, and operates in the second AD conversion mode when being set in a second readout mode of composing and outputting signals from the plurality of photoelectric conversion portions.

2. The apparatus according to claim 1, wherein the first readout mode is a mode for one of focus detection and distance measurement, and the second readout mode is a mode for image capture.

3. The apparatus according to claim 1, wherein the first AD conversion mode and the second AD conversion mode differ in AD conversion resolution.

4. The apparatus according to claim 3, wherein the first AD conversion mode is lower in AD conversion resolution than the second AD conversion mode.

5. The apparatus according to claim 1, further comprising composing unit configured to compose signals output in the first AD conversion mode.

6. The apparatus according to claim 1, further comprising arithmetic unit configured to calculate distance measurement information from signals output in the first AD conversion mode.

7. The apparatus according to claim 1, wherein each of the unit pixels comprises one microlens.

8. An image capturing apparatus comprising:
a plurality of unit pixels arranged in matrix and each including a photoelectric conversion portion and a plurality of transfer transistors; and
an AD converter configured to receive a signal from the unit pixel and operate in one of a first AD conversion mode and a second AD conversion mode different from the first AD conversion mode,
wherein the AD converter operates in the first AD conversion mode when being set in a first readout mode of sequentially driving the plurality of transfer transistors and outputting signals from the photoelectric conversion portion, and operates in the second AD conversion mode when being set in a second readout mode of driving any or all of the plurality of transfer transistors at the same time and outputting signals from the photoelectric conversion portion.

9. The apparatus according to claim 8, wherein the first readout mode is a mode for one of focus detection and distance measurement, and the second readout mode is a mode for image capture.

10. The apparatus according to claim 8, wherein the first AD conversion mode and the second AD conversion mode differ in AD conversion resolution.

11. The apparatus according to claim 10, wherein the first AD conversion mode is lower in AD conversion resolution than the second AD conversion mode.

12. The apparatus according to claim 8, further comprising composing unit configured to compose signals output in the first AD conversion mode.

13. The apparatus according to claim 8, further comprising arithmetic unit configured to calculate distance measurement information from signals output in the first AD conversion mode.

14. The apparatus according to claim 8, wherein each of the unit pixels comprises one microlens.

15. The apparatus according to claim 8, further comprising projection unit configured to project pulse light onto an object, wherein distance measurement is performed based on reflected light of the pulse light.

16. An image capturing apparatus having a plurality of unit pixels arranged in matrix and each including a plurality of photoelectric conversion portions, comprising:
control unit configured to perform control such that a resolution of a pixel signal in a first readout mode of independently outputting signals from the plurality of photoelectric conversion portions is lower than a resolution of a pixel signal in a second readout mode of composing and outputting signals from the plurality of photoelectric conversion portions.

17. An image capturing apparatus having a plurality of unit pixels arranged in matrix and each including a photoelectric conversion portion and a plurality of transfer transistors, comprising
control unit configured to perform control such that a resolution of a pixel signal in a first readout mode of sequentially driving the plurality of transfer transistors and outputting signals from the photoelectric conversion portion is lower than a resolution of a pixel signal in a second readout mode of driving any or all of the plurality of transfer transistors at the same time and outputting signals from the photoelectric conversion portion.

18. A method of controlling an image capturing apparatus including a plurality of unit pixels arranged in matrix and each including a plurality of photoelectric conversion portions, comprising
receiving a signal from the unit pixel and operating in one of a first AD conversion mode and a second AD conversion mode different from the first AD conversion mode,
wherein in the operating, an operation is performed in the first AD conversion mode when setting a first readout mode of independently outputting signals from the plurality of photoelectric conversion portions, and an operation is performed in the second AD conversion mode when setting a second readout mode of composing and outputting signals from the plurality of photoelectric conversion portions.

19. A method of controlling an image capturing apparatus including a plurality of unit pixels arranged in matrix and each including a photoelectric conversion portion and a plurality of transfer transistors, comprising
receiving a signal from the unit pixel and operating in one of a first AD conversion mode and a second AD conversion mode different from the first AD conversion mode,
wherein in the operating, an operation is performed in the first AD conversion mode when setting a first readout mode of sequentially driving the plurality of transfer transistors and outputting signals from the photoelectric conversion portion, and an operation is performed in the second AD conversion mode when setting a second readout mode of driving any or all of the plurality of transfer transistors at the same time and outputting signals from the photoelectric conversion portion.

20. A method of controlling an image capturing apparatus including a plurality of unit pixels arranged in matrix and each including a plurality of photoelectric conversion portions, comprising
performing control such that a resolution of a pixel signal in a first readout mode of independently outputting signals from the plurality of photoelectric conversion portions is lower than a resolution of a pixel signal in a second readout mode of composing and outputting signals from the plurality of photoelectric conversion portions.

21. A method of controlling an image capturing apparatus including a plurality of unit pixels arranged in matrix and each including a photoelectric conversion portion and a plurality of transfer transistors, comprising
performing control such that a resolution of a pixel signal in a first readout mode of sequentially driving the plurality of transfer transistors and outputting signals from the photoelectric conversion portion is lower than a resolution of a pixel signal in a second readout mode of driving any or all of the plurality of transfer transistors at the same time and outputting signals from the photoelectric conversion portion.
